(19) United States
(12) Patent Application Publication
(10) Pub. No.: US 2015/0034148 A1
(43) Pub. Date: Feb. 5, 2015

(54) LIQUID FLUOROPOLYMER COATING COMPOSITION, FLUOROPOLYMER COATED FILM, AND PROCESS FOR FORMING THE SAME

(71) Applicant: E I DU PONT DE NEMOURS AND COMPANY, Wilmington, DE (US)

(72) Inventor: DONALD DOUGLAS MAY, Chadds Ford, PA (US)

(21) Appl. No.: 14/333,587

(22) Filed: Jul. 17, 2014

Related U.S. Application Data
(60) Provisional application No. 61/861,486, filed on Aug. 2, 2013.

(51) Int. Cl. H01L 31/048; B05D 3/02; C08K 3/22; B05D 3/04; C09D 127/16; C08K 3/00

(52) U.S. Cl. CPC H01L 31/0487; C09D 127/16; C08K 3/0033; C08K 3/22; B05D 3/0406; B05D 3/0272; C08K 2003/2241
USPC 136/252; 428/421; 428/412; 524/545; 427/393.5

(57) ABSTRACT

In a first aspect, a liquid fluoropolymer coating composition includes a fluoropolymer selected from homopolymers and copolymers of vinyl fluoride and homopolymers and copolymers of vinylidene fluoride, a mixed catalyst, solvent, a compatible cross-linkable adhesive polymer and a cross-linking agent. The mixed catalyst includes a main catalyst and a co-catalyst. The main catalyst includes an organotin compound.

In a second aspect, a fluoropolymer coated film includes a polymeric substrate film and a fluoropolymer coating on the polymeric substrate film. The fluoropolymer coating includes a fluoropolymer selected from homopolymers and copolymers of vinyl fluoride and homopolymers and copolymers of vinylidene fluoride, a compatible cross-linked adhesive polymer, and a mixed catalyst. The mixed catalyst includes a main catalyst and a co-catalyst. The main catalyst includes an organotin compound.

In a third aspect, a process for forming a fluoropolymer coated film includes coating a polymeric substrate film with a liquid fluoropolymer coating.

### BACKGROUND INFORMATION

1. Field of the Disclosure

This disclosure relates to a liquid fluoropolymer coating composition, a fluoropolymer coated film, and a process for forming a fluoropolymer coated film.

2. Description of the Related Art

Photovoltaic (PV) cells are used to produce electrical energy from sunlight, offering a more environmentally friendly alternative to traditional methods of electricity generation. These solar cells are built from various semiconductor systems which must be protected from environmental effects such as moisture, oxygen, and UV light. The cells are usually jacketed on both sides by encapsulating layers of glass and/or plastic films forming a multilayer structure known as a photovoltaic module. Fluoropolymer films are recognized as an important component in photovoltaic modules due to their excellent strength, weather resistance, UV resistance, and moisture barrier properties. Especially useful in these modules are film composites of fluoropolymer film and polymeric substrate film which act as a backing sheet for the module. Such composites have traditionally been produced from preformed films of fluoropolymer, specifically polyvinyl fluoride (PVF), adhered to polyester substrate film, specifically polyethylene terephthalate. When fluoropolymer such as PVF is used as a backsheet for the PV module, its properties significantly improve the module life, enabling module warranties of up to 25 years. Fluoropolymer backsheets are frequently employed in the form of a laminate with polyethylene terephthalate (PET) films, typically with the PET sandwiched between two PVF films.

However, laminates of preformed fluoropolymer films on polymeric substrates having a bond which will not delaminate after years of outdoor exposure are difficult to make. Prior art systems such as U.S. Pat. No. 3,133,854 to Simms, U.S. Pat. No. 5,139,878 to Kim, et al., and No. U.S. Pat. No. 6,632,518 to Schmidt, et al. describe primers and adhesives for preformed films that will produce durable laminate structures. However, these processes require the application of at least one adhesive layer, or both a primer and an adhesive layer, prior to the actual lamination step. The lamination step then requires the application of heat and pressure to form the laminate. Therefore, prior art laminates using preformed fluoropolymer films are expensive to manufacture and/or require capital intensive equipment. Because preformed fluoropolymer films must have sufficient thickness to provide strength for handling during manufacture and subsequent processing, the resulting laminates may also incorporate thick layers of fluoropolymer, i.e., thicker than are necessary for an effective protective layer.

Liquid coating composition can provide thinner fluoropolymer films on polymeric substrates using fewer processing steps. Examples of these systems are described in U.S. Pat. Nos. 7,553,540; 7,981,478; 8,012,542; 8,025,928; 8,048,513; 8,062,744; 8,168,297; and 8,197,933, and U.S. Patent Application Publication Nos. 2011/0086954 and 2012/0116016. Some of these systems include the use of primers on the polymeric substrate to be coated, while other systems disclose fluoropolymer coatings applied directly to unprimed polymeric substrates. In the case of using fluoropolymer coatings applied directly to unprimed polymeric substrates, it can be challenging to achieve sufficient adhesion of the fluoropolymer coating to the polymeric substrate. In particular, incorporating pigments and fillers, UV additives and thermal stabilizers, or other barrier particles into the fluoropolymer coating composition can negatively impact the performance of a backsheet made using a fluoropolymer coating on a polymeric substrate film. In a specific example, different pigment dispersions can reduce the adhesion between a fluoropolymer coating and a polymeric substrate film.

### SUMMARY

The invention provides a fluoropolymer coated polymeric substrate film with fewer overall processing steps than manufacturing laminates with preformed fluoropolymer films, while also providing strong adhesion to the substrate and good durability of the fluoropolymer coated film. In addition, providing the fluoropolymer in the form of a coating enables thinner, more cost effective, fluoropolymer coating layers. Employing fluoropolymer coatings also enables the incorporation of additives into the fluoropolymer layer tailored to the intended use of the fluoropolymer coated film, e.g., fillers which can improve barrier properties.

In a first aspect, a liquid fluoropolymer coating composition includes a fluoropolymer selected from homopolymers and copolymers of vinyl fluoride and homopolymers and copolymers of vinylidene fluoride, a mixed catalyst, solvent, a compatible cross-linkable adhesive polymer and a cross-linking agent. The mixed catalyst includes a main catalyst and a co-catalyst. The main catalyst includes an organotin compound.

In a second aspect, a fluoropolymer coated film includes a polymeric substrate film and a fluoropolymer coating on the polymeric substrate film. The fluoropolymer coating includes a fluoropolymer selected from homopolymers and copolymers of vinyl fluoride and homopolymers and copolymers of vinylidene fluoride, a compatible cross-linked adhesive polymer, and a mixed catalyst. The mixed catalyst includes a main catalyst and a co-catalyst. The main catalyst includes an organotin compound. The polymeric substrate film includes functional groups that interact with the compatible cross-linked adhesive polymer to promote bonding of the fluoropolymer coating to the polymeric substrate film.

In a third aspect, a process for forming a fluoropolymer coated film includes coating a polymeric substrate film with a liquid fluoropolymer coating. The liquid fluoropolymer coating includes a fluoropolymer selected from homopolymers and copolymers of vinyl fluoride and homopolymers and copolymers of vinylidene fluoride, a mixed catalyst, solvent, a compatible cross-linkable adhesive polymer and a cross-linking agent. The mixed catalyst includes a main catalyst and a co-catalyst. The main catalyst includes an organotin compound. The process further includes cross-linking the compatible cross-linkable adhesive polymer to form a cross-linked polymer network in the fluoropolymer coating, removing the solvent from the fluoropolymer coating and adhering the fluoropolymer coating to the polymeric substrate film.

The foregoing general description and the following detailed description are exemplary and explanatory only and are not restrictive of the invention, as defined in the appended claims.

### DETAILED DESCRIPTION

In a first aspect, a liquid fluoropolymer coating composition includes a fluoropolymer selected from homopolymers and copolymers of vinyl fluoride and homopolymers and copolymers of vinylidene fluoride, a mixed catalyst, solvent, a compatible cross-linkable adhesive polymer and a cross-linking agent. The mixed catalyst includes a main catalyst and a co-catalyst. The main catalyst includes an organotin compound.

In one embodiment of the first aspect, the organotin compound is selected from the group consisting of dibutyl tin dilaurate, dibutyl tin dichloride, stannous octanoate, dibutyl tin dilaurylmercaptide, dibutyltin diisooctylmaleate, and mixtures thereof.

In another embodiment of the first aspect, the co-catalyst is selected from the group consisting of organozinc compounds, organobismuth compounds, and mixtures thereof.

In still another embodiment of the first aspect, the compatible cross-linkable adhesive polymer includes polycarbonate polyol.

In yet another embodiment of the first aspect, the cross-linking agent includes a blocked isocyanate functional compound.

In still yet another embodiment of the first aspect, the liquid fluoropolymer coating composition further includes pigment. In a more specific embodiment, the pigment includes titanium dioxide.

In a further embodiment of the first aspect, the mixed catalyst has a solids weight ratio of main catalyst to co-catalyst in a range of from about 0.005:1 to about 200:1. In a more specific embodiment, the solids weight ratio is in a range of from about 0.1:1 to about 2:1.

In still a further embodiment of the first aspect, the main catalyst is present in a range of from about 0.005 to about 0.1 parts per hundred parts fluoropolymer resin solids. In a more specific embodiment, the main catalyst is present in a range of from about 0.01 to about 0.02 parts per hundred parts fluoropolymer resin solids.

In yet a further embodiment of the first aspect, the co-catalyst is present in a range of from about 0.05 to about 1 parts per hundred parts fluoropolymer resin solids. In a more specific embodiment, the co-catalyst is present in a range of from about 0.1 to about 0.2 parts per hundred parts fluoropolymer resin solids.

In a second aspect, a fluoropolymer coated film includes a polymeric substrate film and a fluoropolymer coating on the polymeric substrate film. The fluoropolymer coating includes a fluoropolymer selected from homopolymers and copolymers of vinyl fluoride and homopolymers and copolymers of vinylidene fluoride, a compatible cross-linked adhesive polymer, and a mixed catalyst. The mixed catalyst includes a main catalyst and a co-catalyst. The main catalyst includes an organotin compound. The polymeric substrate film includes functional groups that interact with the compatible cross-linked adhesive polymer to promote bonding of the fluoropolymer coating to the polymeric substrate film.

In one embodiment of the second aspect, the co-catalyst is selected from the group consisting of organozinc compounds, organobismuth compounds, and mixtures thereof.

In another embodiment of the second aspect, the fluoropolymer coating further includes pigment. In a more specific embodiment, the pigment includes titanium dioxide.

In still another embodiment of the second aspect, the compatible cross-linked adhesive polymer is selected from polyester urethanes, polycarbonate urethanes, acrylic polyurethanes, polyether urethanes, ethylene vinyl alcohol copolymer urethanes, polyamide urethanes, polyacrylamide urethanes and combinations thereof.

In yet another embodiment of the second aspect, the polymeric substrate film includes polyester, polyamide, polyimide, or any combination thereof.

In still yet another embodiment of the second aspect, a backsheet for a photovoltaic module includes the fluoropolymer coated film.

In a third aspect, a process for forming a fluoropolymer coated film includes coating a polymeric substrate film with a liquid fluoropolymer coating. The liquid fluoropolymer coating includes a fluoropolymer selected from homopolymers and copolymers of vinyl fluoride and homopolymers and copolymers of vinylidene fluoride, a mixed catalyst, solvent, a compatible cross-linkable adhesive polymer and a cross-linking agent. The mixed catalyst includes a main catalyst and a co-catalyst. The main catalyst includes an organotin compound. The process further includes cross-linking the compatible cross-linkable adhesive polymer to form a cross-linked polymer network in the fluoropolymer coating, removing the solvent from the fluoropolymer coating and adhering the fluoropolymer coating to the polymeric substrate film.

Many aspects and embodiments have been described above and are merely exemplary and not limiting. After reading this specification, skilled artisans appreciate that other aspects and embodiments are possible without departing from the scope of the invention. Other features and advantages of the invention will be apparent from the following detailed description, and from the claims.

### Fluoropolymers

Fluoropolymers useful in the fluoropolymer coated film in accordance with one aspect of the invention are selected from homopolymers and copolymers of vinyl fluoride (VF) and homopolymers and copolymers of vinylidene fluoride (VF2). In one embodiment, the fluoropolymer is selected from homopolymers and copolymers of vinyl fluoride comprising at least 60 mole % vinyl fluoride and homopolymers and copolymers of vinylidene fluoride comprising at least 60 mole % vinylidene fluoride. In a more specific embodiment, the fluoropolymer is selected from homopolymers and copolymers of vinyl fluoride comprising at least 80 mole % vinyl fluoride and homopolymers and copolymers of vinylidene fluoride comprising at least 80 mole % vinylidene fluoride. Blends of the fluoropolymers with nonfluoropolymers, e.g., acrylic polymers, may also be suitable for the practice of some aspects of the invention. Homopolymer polyvinyl fluoride (PVF) and homopolymer polyvinylidene fluoride (PVDF) are well suited for the practice of specific aspects of the invention. Fluoropolymers selected from homopolymer polyvinyl fluoride and copolymers of vinyl fluoride are particularly effective for the practice of the present invention.

In one embodiment, with VF copolymers or VF2 copolymers, comonomers can be either fluorinated or nonfluorinated or combinations thereof. By the term “copolymers” is meant copolymers of VF or VF2 with any number of additional fluorinated or non-fluorinated monomer units so as to form dipolymers, terpolymers, tetrapolymers, etc. If nonfluorinated monomers are used, the amount used should be limited so that the copolymer retains the desirable properties of the fluoropolymer, i.e., weather resistance, solvent resistance, barrier properties, etc. In one embodiment, fluorinated comonomers are used including fluoroolefins, fluorinated vinyl ethers, or fluorinated dioxoles. Examples of useful fluorinated comonomers include tetrafluoroethylene (TFE), hexafluoropropylene (HFP), chlorotrifluoroethylene (CTFE), trifluoroethylene, hexafluoroisobutylene, perfluorobutyl ethylene, perfluoro (propyl vinyl ether) (PPVE), perfluoro (ethyl vinyl ether) (PEVE), perfluoro(methyl vinyl ether) (PMVE), perfluoro-2,2-dimethyl-1,3-dioxole (PDD) and perfluoro-2-methylene-4-methyl-1,3-dioxolane (PMD) among many others.

Homopolymer PVDF coatings can be formed from a high molecular weight PVDF. Blends of PVDF and alkyl(meth)acrylate polymers can be used. Polymethyl methacrylate is particularly desirable. Typically, these blends can comprise 50-70% by weight of PVDF and 30-50% by weight of alkyl(meth)acrylate polymers, in a specific embodiment, polymethyl methacrylate. Such blends may contain compatibilizers and other additives to stabilize the blend. Such blends of polyvinylidene fluoride, or vinylidene fluoride copolymer, and acrylic resin as the principal components are described in U.S. Pat. Nos. 3,524,906; 4,931,324; and 5,707,697.

Homopolymer PVF coatings can be formed from a high molecular weight PVF. Suitable VF copolymers are taught by U.S. Pat. Nos. 6,242,547 and 6,403,740 to Uschold.

### Compatible Cross-Linkable Adhesive Polymers and Cross-Linking Agents

The compatible cross-linkable adhesive polymers employed in the fluoropolymer coated film according to one aspect of the invention comprise functional groups selected from amine, isocyanate, hydroxyl and combinations thereof. In one embodiment, the compatible cross-linkable adhesive polymer has (1) a backbone composition that is compatible with the fluoropolymer in the composition and (2) pendant functionality capable of reacting with complementary functional groups on a substrate film surface. The compatibility of the cross-linkable adhesive polymer backbone with the fluoropolymer will vary but is sufficient so that the compatible cross-linkable adhesive polymer can be introduced into the fluoropolymer in the desired amount to secure the fluoropolymer coating to the polymeric substrate film. In general however, homo and copolymers derived largely from vinyl fluoride and vinylidene fluoride will show compatibility characteristics that will favor acrylic, urethane, aliphatic polyester, polyester urethane, polyether, ethylene vinyl alcohol copolymer, amide, acrylamide, urea and polycarbonate backbones having the functional groups described above.

In a specific embodiment, where the polymeric substrate film is an unmodified polyester with intrinsic hydroxyl and carboxylic acid functional groups, reactive polyols (e.g., polyester polyols, polycarbonate polyols, acrylic polyols, polyether polyols, etc.) can be used as the compatible cross-linkable adhesive polymer in the presence of an appropriate cross-linking agent (e.g., an isocyanate functional compound or a blocked isocyanate functional compound) to bond the fluoropolymer coating to the polymeric substrate film. The bonding may occur through the functional groups of the reactive polyols, the cross-linking agent, or both. Upon curing, a cross-linked adhesive polymer, such as a cross-linked polyurethane network is formed as an interpenetrating network with the fluoropolymer in the coating. In addition, it is believed that the cross-linked polyurethane network also provides the functionality that bonds the fluoropolymer coating to the polyester substrate film.

Those skilled in the art will understand that choices for compatible cross-linkable adhesive polymers and cross-linking agents can be based on compatibility with the fluoropolymer, compatibility with the selected fluoropolymer solution or dispersion, their compatibility with the processing conditions for forming the fluoropolymer coating on the selected polymeric substrate film, their ability to form cross-linked networks during formation of the fluoropolymer coating, and/or the compatibility of their functional groups with those of the polymeric substrate film in forming bonds that provide strong adherence between the fluoropolymer coating and the polymeric substrate film.

### Mixed Catalyst Systems

Addition of a suitable mixed catalyst system can accelerate the rate of reaction in order to achieve a commercially viable process. The term “mixed catalyst” when used herein, refers to a catalyst system in which at least two different compounds act as catalysts for chemical reaction in a single system. In one embodiment of a mixed catalyst system, a main catalyst may be an organotin compound, and a co-catalyst may be selected from the group consisting of organozincs, organobismuths, and mixtures thereof. Suitable organotin compounds include, but are not limited to, dibutyl tin dilaurate (DBTDL), dibutyl tin dichloride, stannous octanoate, dibutyl tin dilaurylmercaptide and dibutyltin diisooctylmaleate.

In one embodiment, wherein the co-catalyst includes an organozinc compound, the co-catalyst can include a zinc carboxylate or an organozinc acetylacetone complex. Examples of suitable organozinc compounds include zinc acetylacetonate, zinc neodecanoate, zinc octanoate and zinc oleate. Suitable organozinc compounds also include BiCAT® 3228 and BiCAT® Z (The Shepherd Chemical Co., Norwood, Ohio).

In another embodiment, wherein the co-catalyst includes an organobismuth compound, the co-catalyst can include an organobismuth carboxylate complex. Examples of suitable organobismuth compounds include K-KAT 348 and K-KAT 628 (King Industries, Inc. Norwalk, Conn.), and BiCAT® 8, BiCAT® 8106, BiCAT® 8108 and BiCAT® 8210 (Shepherd Chemical).

Numerous combinations of organotin catalysts with co-catalysts comprising organozincs, organobismuths, and mixtures thereof may be useful in the liquid fluoropolymer coating compositions described herein. Those skilled in the art will be able to select an appropriate mixed catalyst system based on the properties of the polymer system being used in the process and the desired properties of the final fluoropolymer coated film.

### Pigments and Fillers

If desired, various color, opacity and/or other property effects can be achieved by incorporating pigments and fillers into the fluoropolymer coating composition dispersion during manufacture. In one embodiment, pigments are used in amounts of from about 1 to about 35 wt % based on fluoropolymer resin solids. Typical pigments that can be used include both clear pigments, such as inorganic siliceous pigments (silica pigments, for example) and conventional pigments. Conventional pigments that can be used include metallic oxides such as titanium dioxide, and iron oxide; metal hydroxides; metal flakes, such as aluminum flake; chromates, such as lead chromate; sulfides; sulfates; carbonates; carbon black; silica; talc; china clay; phthalocyanine blues and greens, organo reds; organo maroons and other organic pigments and dyes. In one embodiment, the type and amount of pigment is selected to prevent any significant adverse affects on the desirable properties of fluoropolymer coating, e.g., weatherability, as well as being selected for stability at the elevated processing temperatures that may be used during film formation.

In one embodiment, pigments can be formulated into a millbase by mixing the pigment(s) with a dispersing resin that may be the same as or compatible with the fluoropolymer composition into which the pigment is to be incorporated. Pigment dispersions can be formed by conventional means, such as sand grinding, ball milling, attritor grinding or two-roll milling. Other additives, while not generally needed or used, such as fiber glass and mineral fillers, anti-slip agents, plasticizers, nucleating agents, and the like, can also be incorporated.

In one embodiment, titanium dioxide (TiO₂) may be used as a pigment. The TiO₂ can comprise rutile, anatase, or a combination thereof, although rutile is generally preferred due to its superior photodurability. In one embodiment, the TiO₂ may have a primary particle size of from about 0.1 to about 1.0 μm, or from about 0.2 to about 0.35 μm. As used herein, the term “primary particle size” is meant to refer to the size of individual particles, as opposed to the size of agglomerates of particle. For example, TiO₂ having a primary particle size of from about 0.1 to about 1.0 μm may form agglomerates that are much larger in size when in a pigment dispersion. In one embodiment, the TiO₂ may be surface treated with silica, alumina or a combination thereof. In one embodiment, the TiO₂ may have an organic treatment such as trimethylolpropane, or triethanol amine or any one of the silane or polysiloxane treatments known to those skilled in the art. Various commercial grades of TiO₂ are suitable pigments, including Ti-Pure® R-960, Ti-Pure® R-706 and TS-6200 (all available from the DuPont Co., Wilmington, Del.).

### UV Additives and Thermal Stabilizers

In one embodiment, the fluoropolymer coating compositions may contain one or more light stabilizers as additives. Light stabilizer additives include compounds that absorb ultraviolet radiation such as hydroxybenzophenones and hydroxybenzotriazoles. Other possible light stabilizer additives include hindered amine light stabilizers (HALS) and antioxidants. Thermal stabilizers can also be used, if desired.

### Barrier Particles

In one embodiment, the fluoropolymer coating composition may include barrier particles. In a specific embodiment, the particles may be platelet-shaped particles. Such particles tend to align during application of the coating and, since water, solvent and gases such as oxygen cannot pass readily through the particles themselves, a mechanical barrier is formed in the resulting coating which reduces permeation of water, solvent and gases. In a photovoltaic module, for example, the barrier particles substantially increase the moisture barrier properties of the fluoropolymer and enhance the protection provided to the solar cells. In some embodiments, barrier particles are present in amounts of from about 0.5 to about 10% by weight based on the total dry weight of the fluoropolymer resin solids in the coating.

Examples of typical platelet shaped filler particles include mica, glass flake, stainless steel flake and aluminum flake. In one embodiment, the platelet shaped particles are mica particles, including mica particles coated with an oxide layer such as iron or titanium oxide. In some embodiments, these particles have an average particle size of about 10 to 200 μm, or 20 to 100 μm, with no more than 50% of the particles of flake having average particle size of more than about 300 μm. The mica particles coated with an oxide layer are described in U.S. Pat. No. 3,087,827 (Klenke and Stratton); U.S. Pat. No. 3,087,828 (Linton); and U.S. Pat. No. 3,087,829 (Linton). The micas described in these patents are coated with oxides or hydrous oxides of titanium, zirconium, aluminum, zinc, antimony, tin, iron, copper, nickel, cobalt, chromium, or vanadium. Mixtures of coated micas can also be used.

### Liquid Fluoropolymer Coating Composition

The liquid fluoropolymer coating compositions may contain the fluoropolymer either in the form of a solution or dispersion of the fluoropolymer. Typical solutions or dispersions for the fluoropolymer are prepared using solvents which have boiling points high enough to avoid bubble formation during the film forming/drying process. For polymers in dispersion form, a solvent which aids in coalescence of the fluoropolymer is desirable. The polymer concentration in these solutions or dispersions is adjusted to achieve a workable viscosity of the solution and will vary with the particular polymer, the other components of the coating composition, and the process equipment and conditions used. In one embodiment, for solutions, the fluoropolymer is present in an amount of about 10 wt % to about 25 wt % based on the total weight of the liquid fluoropolymer coating composition. In another embodiment, for dispersions, the fluoropolymer is present in an amount of about 25 wt % to about 50 wt % based on the total weight of the liquid fluoropolymer coating composition.

The form of the polymer in the liquid fluoropolymer coating composition is dependent upon the type of fluoropolymer and the solvent used. Homopolymer PVF is normally in dispersion form. Homopolymer PVDF can be in dispersion or solution form dependent upon the solvent selected. For example, homopolymer PVDF can form stable solutions at room temperature in many polar organic solvents such as ketones, esters and some ethers. Suitable examples include acetone, methylethyl ketone (MEK) and tetrahydrofuran (THF). Depending upon comonomer content and the solvent selected, copolymers of VF and VF2 may be used either in dispersion or solution form.

In one embodiment, using homopolymer polyvinyl fluoride (PVF), suitable coating formulations are prepared using dispersions of the fluoropolymer. The nature and preparation of dispersions are described in detail in U.S. Pat. Nos. 2,419,008; 2,510,783; and 2,599,300. In a specific embodiment, PVF dispersions are formed in dimethyl acetamide, propylene carbonate, γ-butyrolactone, N-methyl pyrrolidone, or dimethylsulfoxide.

To prepare the liquid fluoropolymer coating composition in dispersion form, the fluoropolymer and the compatible cross-linkable adhesive polymer, the cross-linking agent, and, optionally one or more dispersants and/or pigments, are generally first milled together in a suitable solvent. Alternatively, the fluoropolymer is milled and the crosslinkable ingredients appropriately mixed separately. Components which are soluble in the solvent do not require milling.

A wide variety of mills can be used for the preparation of the dispersion. Typically, the mill employs a dense agitated grinding medium, such as sand, steel shot, glass beads, ceramic shot, Zirconia, or pebbles, as in a ball mill, an ATTRITOR® available from Union Process, Akron, Ohio, or an agitated media mill such as a “Netzsch” mill available from Netzsch, Inc., Exton, Pa. The dispersion is milled for a time sufficient to cause deagglomeration of the PVF. Typical residence time of the dispersion in a Netzsch mill ranges from thirty seconds up to ten minutes.

The compatible cross-linkable adhesive polymer is employed in the liquid fluoropolymer coating composition at a level sufficient to provide the desired bonding to the polymeric substrate film but below the level at which the desirable properties of the fluoropolymer would be significantly adversely affected. In one embodiment, the liquid fluoropolymer coating composition contains from about 1 to about 40 wt % compatible cross-linkable adhesive polymer, or from about 1 to about 25 wt %, or from about 1 to about 20 wt %, based on the weight of the fluoropolymer.

The cross-linking agent is employed in the liquid coating composition at a level sufficient to provide the desired cross-linking of the compatible cross-linkable adhesive polymer. In one embodiment, the liquid coating composition contains from about 50 to about 400 mole % cross-linking agent per molar equivalent of cross-linkable adhesive polymer, or from about 75 to about 200 mole %, or from about 125 to about 175 mole %.

The amount of mixed catalyst used is typically kept to a minimum since extra main catalyst, as well as extra co-catalyst, can be detrimental to long term damp heat adhesion performance of a fluoropolymer coating on a polymeric substrate film formed using the liquid fluoropolymer coating composition. In one embodiment, an organotin catalyst can be used as a main catalyst, and can be present in a range of from about 0.005 to about 0.1 parts per hundred (pph), dry basis, of main catalyst to fluoropolymer resin solids, or from about 0.01 to about 0.05 pph, or from about 0.01 to about 0.02 pph. In one embodiment, the co-catalyst can be an organobismuth compound or an organozinc compound and can be present in a range of from about 0.05 to about 1.0 pph, dry basis, of co-catalyst to fluoropolymer resin solids, or from about 0.1 to about 0.5 pph, or from about 0.1 to about 0.2 pph.

The solids weight ratio of main catalyst to co-catalyst used in a mixed catalyst system can vary over a broad range. In one embodiment, the solids weight ratio of main catalyst to co-catalyst can be in a range of from about 0.005:1 to about 200:1, or from about 0.05:1 to about 50:1, or from about 0.1:1 to about 2:1.

The amount of mixed catalyst used and the solids weight ratio of main catalyst to co-catalyst in the mixed catalyst will affect the cure time needed to produce good adhesion of a fluoropolymer coating to a polymeric substrate film.

Polymeric Substrate Films Polymeric substrate films may be selected from a wide range of polymers, with thermoplastics being desirable for their ability to withstand higher processing temperatures. The polymeric substrate film comprises functional groups on its surface that interact with the compatible cross-linkable adhesive polymer, the cross-linking agent, or both, to promote bonding of the fluoropolymer coating to the polymeric substrate film. In one embodiment, the polymeric substrate film is a polyester, a polyamide or a polyimide. In a specific embodiment, a polyester for the polymeric substrate film is selected from polyethylene terephthalate, polyethylene naphthalate and a coextrudate of polyethylene terephthalate/polyethylene naphthalate.

Fillers may also be included in the substrate film, where their presence may improve the physical properties of the substrate, for example, higher modulus and tensile strength. They may also improve adhesion of the fluoropolymer coating to the polymeric substrate film. One exemplary filler is barium sulfate, although others may also be used.

The surface of the polymeric substrate film which is to be coated may naturally possess functional groups suitable for bonding, as in hydroxyl and/or carboxylic acid groups in a polyester film, or amine and/or acid functionality in a polyamide film. The presence of these intrinsic functional groups on the surface of a polymeric substrate film clearly provide commercial benefits by simplifying the process of bonding a coating onto the polymeric substrate film to form a fluoropolymer coated film. The invention employs compatible cross-linkable adhesive polymers and/or cross-linking agents in the coating composition that may take advantage of the intrinsic functionality of the polymeric substrate film. In this way, an unmodified polymeric substrate film can be chemically bonded to a fluoropolymer coating (i.e., without the use of separate primer layers or adhesives or separate surface activation treatments) to form a fluoropolymer coated film with excellent adhesion. The term “unmodified polymeric substrate film” as used herein means polymeric substrates which do not include primer layers or adhesives and which do not include surface treatment or surface activation such as are described in the following paragraph. In addition, an unprimed polymeric substrate film can be chemically bonded to a fluoropolymer coating to form a fluoropolymer coated film with excellent adhesion. The term “unprimed polymeric substrate film” as used herein means polymeric substrates which do not include primer layers but may include surface treatment or surface activation such as are described in the following paragraph.

Many polymeric substrate films may need or would further benefit from modifying to provide additional functional groups suitable for bonding to the fluoropolymer coating, however, and this may be achieved by surface treatment, or surface activation. That is, the surface can be made more active by forming functional groups of carboxylic acid, sulfonic acid, aziridine, amine, isocyanate, melamine, epoxy, hydroxyl, anhydride and/or combinations thereof on the surface. In one embodiment, the surface activation can be achieved by chemical exposure, such as to a gaseous Lewis acid such as BF₃ or to sulfuric acid or to hot sodium hydroxide. Alternatively, the surface can be activated by exposing one or both surfaces to an open flame while cooling the opposite surface. Surface activation can also be achieved by subjecting the film to a high frequency, spark discharge such as corona treatment or atmospheric nitrogen plasma treatment. Additionally, surface activation can be achieved by incorporating compatible comonomers into the polymeric substrate when forming a film. Those skilled in the art, will appreciate the wide variety of processes that may be used to form compatible functional groups on the surface of a polymeric substrate film.

In addition, modifying to provide additional functional groups suitable for bonding to the fluoropolymer coating may be performed by applying a primer layer to the surface of the polymeric substrate film to increase its surface functionality, as described in U.S. Pat. No. 7,553,540, DeBergalis et al., which is incorporated herein by reference in its entirety.

### Coating Application

The fluoropolymer compositions for making the fluoropolymer coated film in accordance with one aspect of the present invention can be applied as a liquid directly to suitable polymeric substrate films by conventional coating means with no need to form a preformed film. Techniques for producing such coatings include conventional methods of casting, dipping, spraying and painting. When the fluoropolymer coating contains fluoropolymer in dispersion form, it is typically applied by casting the dispersion onto the substrate film, using conventional means, such as spray, roll, knife, curtain, gravure coaters, or any other method that permits the application of a uniform coating without streaks or other defects. In one embodiment, the dry coating thickness of a cast dispersion is between about 2.5 μm (0.1 mil) and about 250 μm (10 mils), and in a more specific embodiment, between about 13 μm (0.5 mil) to about 130 μm (5 mils).

After application, the compatible cross-linkable adhesive polymer is cross-linked to form a compatible cross-linked adhesive polymer, the solvent is removed, and the fluoropolymer coating is adhered to the polymeric substrate film. With some compositions in which the fluoropolymer is in solution form, the liquid fluoropolymer coating compositions can be coated onto polymeric substrate films and allowed to air dry at ambient temperatures. Although not necessary to produce a coalesced film, heating is generally desirable to cross-link the compatible cross-linkable adhesive polymer and to dry the fluoropolymer coating more quickly. Cross-linking the compatible cross-linkable adhesive polymer, removing of the solvent, and adhering of the fluoropolymer coating to the polymeric substrate can be achieved in a single heating or by multiple heatings. Drying temperature are in the range of about 25° C. (ambient conditions) to about 220° C. (oven temperature—the film temperature will be lower). The temperature used should also be sufficient to promote the interaction of the functional groups in the compatible cross-linkable adhesive polymer and/or cross-linking agent with the functional groups of the polymeric substrate film to provide secure bonding of the fluoropolymer coating to the polymeric substrate film. This temperature varies widely with the compatible cross-linkable adhesive polymer and cross-linking agent employed and the functional groups of substrate film. The drying temperature can range from room temperature to oven temperatures in excess of that required for the coalescence of fluoropolymers in dispersion form as discussed below.

When the fluoropolymer in the composition is in dispersion form, it is necessary for the solvent to be removed, for cross-linking of the compatible adhesive polymer to occur, and also for the fluoropolymer to be heated to a sufficiently high temperature that the fluoropolymer particles coalesce into a continuous film. In addition, bonding to the polymeric substrate film is desired. In one embodiment, fluoropolymer in the coating is heated to a cure temperature of about 150° C. to about 250° C. The solvent used desirably aids in coalescence, i.e., enables a lower temperature to be used for coalescence of the fluoropolymer coating than would be necessary with no solvent present. Thus, the conditions used to coalesce the fluoropolymer will vary with the fluoropolymer used, the thickness of the cast dispersion and the substrate film, and other operating conditions. For homopolymer PVF coatings and residence times of about 1 to about 3 minutes, oven temperatures of from about 340° F. (171° C.) to about 480° F. (249° C.) can be used to coalesce the film, and temperatures of about 380° F. (193° C.) to about 450° F. (232° C.) have been found to be particularly satisfactory. The oven air temperatures, of course, are not representative of the temperatures reached by the fluoropolymer coating which will be lower.

Formation of a cross-linked network of compatible cross-linked adhesive polymer in the presence of the coalescing fluoropolymer can result in the formation of interpenetrating networks of compatible cross-linked adhesive polymer and fluoropolymer, creating an interlocked network. Thus, even if there is segregation or phase separation of the two polymer networks within the fluoropolymer coating and an absence of chemical bonding between the two networks, a strong durable coating is still formed. As long as there is adequate bonding between the compatible cross-linked adhesive polymer and the polymeric substrate film, excellent adhesion between the layers of the fluoropolymer coated film can be attained.

The fluoropolymer coating composition is applied to a polymeric substrate film. In one embodiment, the polymeric substrate film is polyester, polyamide, or polyimide. In a specific embodiment, the polymeric substrate film is polyester such as polyethylene terephthalate, polyethylene napthalate or a coextrudate of polyethylene terephthalate/polyethylene naphthalate. In another embodiment, the fluoropolymer coating is applied to both surfaces of the substrate film. This can be performed simultaneously on both sides of the polymeric substrate film or alternatively, the coated substrate film can be dried, turned to the uncoated side and resubmitted to the same coating head to apply coating to the opposite side of the film to achieve coating on both sides of the film.

### Photovoltaic Modules

Fluoropolymer coated films are especially useful in photovoltaic modules. A typical construction for a photovoltaic module includes a thick layer of glass as a glazing material. The glass protects solar cells comprising crystalline silicon wafers and wires which are embedded in a moisture resisting plastic sealing compound such as cross-linked ethylene vinyl acetate. Alternatively thin film solar cells can be applied from various semiconductor materials, such as CIGS (copper-indium-gallium-selenide), CTS (cadmium-tellurium-sulfide), a-Si (amorphous silicon) and others on a carrier sheet which is also jacketed on both sides with encapsulant materials. Adhered to the encapsulant is a backsheet. Fluoropolymer coated films are useful for such backsheets. The fluoropolymer coating comprises fluoropolymer selected from homopolymers and copolymers of vinyl fluoride and homopolymers and copolymers of vinylidene fluoride polymer blended with compatible cross-linkable adhesive polymer containing functional groups selected from carboxylic acid, sulfonic acid, aziridine, anhydride, amine, isocyanate, melamine, epoxy, hydroxyl, and combinations thereof. The polymeric substrate film comprises functional groups on its surface that interact with the compatible cross-linkable adhesive polymer to promote bonding of the fluoropolymer coating to the substrate film. In one embodiment, the polymeric substrate film is a polyester, and in a more specific embodiment, a polyester selected from the group consisting of polyethylene terephthalate, polyethylene naphthalate and a coextrudate of polyethylene terephthalate/polyethylene naphthalate. Polyester provides electrical insulation and moisture barrier properties, and is an economical component of the backsheet. In some embodiments, both surfaces of the polymeric substrate film are coated with fluoropolymer creating a sandwich of polyester between two layers of coating of fluoropolymer. Fluoropolymer films provide excellent strength, weather resistance, UV resistance, and moisture barrier properties to the backsheet.

### EXAMPLES

The concepts described herein will be further described in the following examples, which do not limit the scope of the invention described in the claims.

### General

Stock Resin Solution A: Into a 4:1 (w/w) mixture of propylene carbonate:butoxy ethyl acetate (PC:BEA), 36.5 wt % PVF polymer is dispersed. Into this dispersion is added 5 wt % (based on PVF solids) of Desmophen® C-3100 (Bayer Material Science, Pittsburgh, Pa.).
Isocyanate Solution C: 7.4 wt % solution of Desmodur® N-3300 (Bayer Material Science) in BEA.
Isocyanate Solution BC: 14.8 wt % solution of Desmodur® PL-350 (Bayer Material Science) in BEA.
Pigment Dispersion: 70 wt % TiO₂ Ti-Pure® R-960 dispersed with 8.9 wt % RK-87763 (DuPont) in BEA or N-methyl pyrollidone (NMP).

### Test Methods

### 180 Degree Peel Strength

Peel strength is measured using an Instron® Model 3345 Single Column Testing System (Instron, Norwood, Mass.) pulling at 10 inches per minute, recording the peak value and averaging 3 samples (following the procedure in ASTM D1876-01 T-Peel Test). If a sample could not be cleanly pulled without the coating tearing, it was assigned a value of 6 N/cm, the maximum force which was able to be measured for a 25 μm coating.

### Initial Adhesion Peel Test

Samples were precision precut into ½ inch strips. The strips were tested for adhesion by placing a piece of 8981 Scotch® Strapping Tape (3M, St. Paul, Minn.) on the side to be peeled and cutting the back side of the film. The film was snapped and the tape used to help start the peel. Well adhering samples tore immediately, those with good, but non-measurable, adhesion tore where the tape backing ended. Finally, samples that did not tear (which were peeling only) were placed in the Instron® Model 3345 and measured according to ASTM D1876-01.

### Autoclave Exposed Peel Test

Samples were precision precut into ½ inch strips prior to insertion into an autoclave at 105° C. and 5 psig steam pressure. After removal from the autoclave, the strips were tested for adhesion using the method described above for initial adhesion.

### Examples 1 to 12 and Comparative Examples 1 and 2

Coating compositions were made from 148 g of stock resin solution A by adding various catalyst solutions. To each of these coating compositions, 19.7 g of isocyanate solution C or BC was added, catalyst amounts as indicated in Table 1, and then 32 g of TiO₂ pigment dispersion. Each coating composition was stirred for 2 minutes, and then coated as a 5 mil thick wet drawdown on polyester (10 mil corona treated BH116, Nan Ya Plastics Corp., Taiwan) and cured at 220° C. for between 60 and 120 seconds.

The mixed catalysts used in examples 1 to 12 and comparative examples 1 and 2 are listed in Table 1. All amounts listed are based on parts per hundred (pph) fluoropolymer resin solids. In order to accurately add the small amounts of catalyst to laboratory mixes, a stock resin solution was made and diluted with BEA and an appropriate aliquot added to the coating composition.

TABLE 1

| | Pigment | | | Co-Catalyst | Co-Catalyst | Initial |
|---|---|---|---|---|---|---|
| Example | Dispersion | DBTDL | Acetic Acid | Type | Amount | Adhesion |
| CE1 | X | 0.02 | 0.2 | — | 0 | good |
| CE2 | Y | 0.02 | 0.2 | — | 0 | none |
| E1 | Y | 0.015 | 0.15 | Bi | 0.15 | good |
| E2 | Y | 0 | 0 | Bi | 0.15 | none |
| E3 | Y | 0.015 | 0.15 | Bi | 0.15 | good |
| E4 | Y | 0. | 0 | Bi | 0.15 | none |
| E5 | Y | 0.015 | 0.15 | Zn | 0.15 | good |
| E6 | Y | 0 | 0 | Zn | 0.15 | none |
| E7 | Y | 0.015 | 0.15 | Zn | 0.15 | good |
| E8 | Y | 0 | 0 | Zn | 0.15 | none |
| E9 | Y | 0.015 | 0.15 | Zr | 0.15 | none |
| E10 | Y | 0 | 0 | Zr | 0.15 | none |
| E11 | Y | 0.015 | 0.15 | Al | 0.15 | none |
| E12 | Y | 0 | 0 | Al | 0.15 | none |

Initial adhesion was graded as good (coating tears because the strength of adhesion is greater than the strength of the film) or none (film is cleanly able to be peeled from back).

Comparative example 1 (CE1), made with TiO₂ pigment dispersion X (Ti-Pure® R-960) and organotin catalyst (DBTDL), showed good initial adhesion (tears) at all cure times from 60 to 120 seconds.

For comparative example 2 (CE2), the procedure of CE1 was repeated except that TiO₂ pigment dispersion Y (a different sample of Ti-Pure® R-960) was used to make the coating mix. For CE2, there was no adhesion seen under any cure time from 60 to 120 seconds.

Example 1 repeated the procedure of CE2 (with TiO₂ pigment dispersion Y) using a mixed catalyst system, an organotin catalyst (DBTDL, 0.015 pph) with bismuth 2-ethylhexanoic acid co-catalyst (K-KAT 348, 0.15 pph). This coating composition showed good adhesion at all cure times.

Example 1 demonstrates that using a mixed catalyst system overcomes the variable adhesion caused by different pigment dispersions.

When the coating composition of example 1 was repeated without the organotin catalyst, no adhesion was seen (example 2).

Example 3 repeated the procedure of example 1, replacing the bismuth co-catalyst K-KAT 348 with Dabco® MB20, a bismuth neodecanoic metal complex available from Air Products and Chemicals Inc. (Allentown, Pa.). Once again, a coating composition with good initial adhesion was formed at all cure times.

When the coating composition of example 3 was repeated without the organotin catalyst, no adhesion was seen (example 4).

Example 5 repeated the procedure of example 1, replacing the bismuth co-catalyst K-KAT 348 with a zinc catalyst, K-KAT 614 (King Industries). Once again, a coating composition with good initial adhesion was formed at all cure times.

When the coating composition of example 5 was repeated without the organotin catalyst, no adhesion was seen (example 6).

Example 7 repeated the procedure of example 1, replacing the bismuth co-catalyst K-KAT 348 with a zinc catalyst, K-KAT 639 (King Industries). Once again, a coating composition with good initial adhesion was formed at all cure times.

When the coating composition of example 7 was repeated without the organotin catalyst, no adhesion was seen (example 8).

Examples 1 to 8 demonstrate that a variety of organozinc and organobismuth compounds are useful as co-catalysts in a mixed catalyst system with organotin as a main catalyst.

Example 9 repeated the procedure of example 1, replacing the bismuth co-catalyst K-KAT 348 with a zirconium catalyst, K-KAT 209 (King Industries). The coating composition made with this mixed catalyst system showed no initial adhesion at all cure times.

When the coating composition of example 9 was repeated without the organotin catalyst, no adhesion was seen (example 10).

Example 11 repeated the procedure of example 1, replacing the bismuth co-catalyst K-KAT 348 with an aluminum catalyst, K-KAT 5218 (King Industries). The coating composition made with this mixed catalyst system showed no initial adhesion at all cure times.

When the coating composition of example 11 was repeated without the organotin catalyst, no adhesion was seen (example 12).

Examples 9 to 12 highlight the fact that only a select group of organometal compounds are useful as co-catalysts in a mixed catalyst system with organotin catalysts.

### Example 13

To 138 g stock resin solution A was added 14 g of a 40 wt % solution of Kynar® HSV900 resin, a high molecular weight polyvinylidene fluoride (PVDF) homopolymer (Arkema Inc., King of Prussia, Pa.), in a 50:50 mix of propylene carbonate and butoxy ethyl acetate with the mixed catalyst of example 1 (DBTDL and K-KAT 348) and 19.7 g of isocyanate solution C. To this was added 32 g of TiO₂ pigment dispersion Y to form a coating composition that was coated onto polyester (10 mil corona treated BH116) and oven cured at 220° C. for either 60, 75, 90 or 120 seconds. Under all of these curing conditions, the coatings formed had good initial adhesion to the polyester substrate.

This example demonstrates that the adhesion of coating blends of PVF and PVDF benefit from the use of a mixed catalyst system.

### Example 14

To 148 g stock resin solution A with the mixed catalyst of example 1 (DBTDL and K-KAT 348), 19.7 g of isocyanate solution BC was added. To this was added 32 g of TiO₂ pigment dispersion Y to form a coating composition that was coated onto polyester (10 mil corona treated BH116) and oven cured at 220° C. for either 60, 75, 90 or 120 seconds. Under all of these curing conditions, the coatings formed had good initial adhesion to the polyester substrate.

This example demonstrates that the adhesion of coating compositions containing blocked isocyanate functional compounds as cross-linking agents benefit from the use of a mixed catalyst system.

### Examples 15 to 18 and Comparative Examples 3 and 4

To further demonstrate the benefit of the mixed catalyst system on the adhesion of fluoropolymer coatings, a Design of Experiments (DOE) was run with TiO₂ pigment dispersions X and Y and the results are summarized in Table 2. Coating compositions were made with the levels of main catalyst (DBTDL) and co-catalyst (K-KAT 348) in pph resin indicated in Table 2. Into a 5 gallon open bucket was charged 4.6 kg of stock solution A to which 660 g of butoxy ethyl acetate was added. With stirring, 84 g of Desmophen® C-3100 and 98 g of Desmodur® BL 3575 (Bayer Material Science) were added and 3.7 g of a 10:1 weight ratio acetic acid:DBTDL solution and 3.7 g of K-KAT-348 solution. With continued stirring, 1.03 kg of TiO₂ pigment dispersion Y is added and stirred for 2 addition minutes at a rate sufficient to mix the ingredients without entraining excessive air.

The coating compositions were applied with a reverse gravure coater and cured in a horizontal drying oven at 215° C. for times (in seconds) indicated in the column headings of Table 2. Dry coatings of 1 mil (25 μm) in thickness were formed. After coating, the samples were tested for adhesion (shown in N/cm in Table 2), and samples which tore, so that their adhesion could not be measured using the Instron® 3345, were assigned a peel value of 6 N/cm, the strongest peel that could be measured before tearing started. The samples were then placed into an autoclave to simulate accelerated weathering and the adhesion tested after 192 hours of exposure. Preferably, the adhesion after 192 hours exposure is at least 2 N/cm.

Comparative Example 3 (CE3) shows that there is poor initial adhesion (less than 2 N/cm) for shorter cure times with TiO₂ dispersion Y, good initial adhesion is only seen for the longest cure time (75 seconds). The adhesion of CE3 after 192 hours in the autoclave is poor for all cure times.

For examples 15 and 16, the coating application of CE3 was repeated with the addition of 0.1 and 0.2 pph K-KAT 348, respectively. Good adhesion (greater than 2 N/cm) was seen both initially and after 192 hours of autoclave exposure.

TABLE 2

| | | | | Initial Adhesion | | | 192 hr Adhesion | | |
|---|---|---|---|---|---|---|---|---|---|
| Example | DBTDL | K-KAT 348 | TiO₂ dispersion | 75 | 60 | 50 | 75 | 60 | 50 |
| CE3 | 0.02 | 0 | Y | 6 | 1.7 | 0.9 | 1.5 | 0.8 | 0.3 |
| E15 | 0.02 | 0.1 | Y | 6 | 6 | 6 | 2.7 | 3.2 | 3.1 |
| E16 | 0.02 | 0.2 | Y | 6 | 6 | 6 | 2.8 | 2.7 | 2.8 |
| CE4 | 0.02 | 0 | X | 6 | 6 | 6 | 2.7 | 2.8 | 2.6 |
| E17 | 0.02 | 0.1 | X | 6 | 6 | 6 | 2.4 | 2.4 | 2.4 |
| E18 | 0.02 | 0.2 | X | 6 | 6 | 6 | 3.4 | 3.2 | 3.4 |
| CE5 | 0.01 | 0 | Y | 0.3 | 0.6 | 0.3 | 0.7 | 0.2 | 0.2 |
| E19 | 0.01 | 0.1 | Y | 6 | 6 | 5 | 5.2 | 5.1 | 3.2 |
| E20 | 0.01 | 0.2 | Y | 6 | 5.5 | 4.6 | 3.6 | 2.4 | 1.9 |
| CE6 | 0.01 | 0 | X | 6 | 6 | 3.5 | 3.8 | 3.9 | 2.3 |
| E21 | 0.01 | 0.1 | X | 4.8 | 3.8 | 3.7 | 3.3 | 3.8 | 2.8 |
| E22 | 0.01 | 0.2 | X | 6 | 3.9 | 6 | 3.3 | 2.1 | 1.9 |

For comparative example 4 (CE4), a coating composition was prepared as described in CE3, except that TiO₂ pigment dispersion X was used in place of TiO₂ pigment dispersion Y. Good initial adhesion was observed, as well as good adhesion after 192 hours in the autoclave, indicating that in certain TiO₂ dispersions, good adhesion can be achieved with a single catalyst system.

For examples 17 and 18, the coating application of CE4 was repeated with the addition of 0.1 and 0.2 pph K-KAT 348, respectively. Good adhesion was seen both initially and after 192 hours of autoclave exposure.

These examples demonstrate that the use of a mixed catalyst system can improve the adhesion of coating compositions that have poor adhesion with a single catalyst system (CE3) and do not adversely affect the adhesion of coating compositions that have good adhesion with a single catalyst system (CE4).

### Examples 19 to 22 and Comparative Examples 5 and 6

For comparative example 5 (CE5), a coating composition was prepared as described in CE3, except that the amount of DBTDL in the composition was reduced to 0.01 pph. Poor initial adhesion was observed, as well as poor adhesion after 192 hours in the autoclave (Table 2).

For examples 19 and 20, the coating application of CE5 was repeated with the addition of 0.1 and 0.2 pph K-KAT 348, respectively. Good adhesion was seen both initially and after 192 hours of autoclave exposure, except for the shortest cure time (50 seconds) with the higher co-catalyst level (0.2 pph).

For comparative example 6 (CE6), a coating composition was prepared as described in CE5, except that TiO₂ pigment dispersion X was used in place of TiO₂ pigment dispersion Y. Good initial adhesion was observed, as well as good adhesion after 192 hours in the autoclave, indicating that in certain TiO₂ dispersions, good adhesion can be achieved with a single catalyst system even with a lower level of catalyst.

For examples 21 and 22, the coating application of CE6 was repeated with the addition of 0.1 and 0.2 pph K-KAT 348, respectively. Good adhesion was seen both initially and after 192 hours of autoclave exposure, except for the shortest cure time (50 seconds) with the higher co-catalyst level (0.2 pph).

These examples demonstrate that the use of a mixed catalyst system can improve the adhesion of coating compositions that have poor adhesion with a single catalyst system (CE5) and do not adversely affect the adhesion of coating compositions that have good adhesion with a single catalyst system (CE6), even when a lower level of main catalyst is used.

### Examples 23 to 32

For examples 23 to 32, coating compositions were made from 148 g stock resin solution A, with mixed catalyst levels (pph based on fluoropolymer resin solids) as shown in Table 3. The catalyst ratio is the ratio of main catalyst to co-catalyst in parts per hundred based on catalyst resin solids (i.e., pph DBTDL to pph K-KAT 348) for the mixed catalyst system. To this was added 19.7 g of isocyanate solution BC and 32 g of TiO₂ pigment dispersion Y. The coating composition was stirred for 2 minutes, and then drawn down to form a 5 mil thick wet layer on polyester (10 mil corona treated BH116). The coating was cured at 220° C. for times ranging from 60 to 120 seconds as shown in the table.

TABLE 3

| | | K-KAT | Catalyst | Initial Adhesion | | | |
|---|---|---|---|---|---|---|---|
| Example | DBTDL | 348 | Ratio | 60 | 75 | 90 | 120 |
| E23 | 0.005 | 1 | 0.005:1 | none | good | good | good |
| E24 | 0.005 | 0.5 | 0.01:1 | none | none | good | good |
| E25 | 0.005 | 0.25 | 0.02:1 | none | none | none | good |
| E26 | 0.015 | 0.15 | 0.1:1 | good | good | good | good |
| E27 | 0.005 | 0.005 | 1:1 | none | none | none | good |
| E28 | 0.1 | 0.1 | 1:1 | good | good | good | good |
| E29 | 0.1 | 0.05 | 2:1 | good | good | good | good |
| E30 | 0.1 | 0.025 | 4:1 | none | none | good | good |
| E31 | 0.1 | 0.005 | 20:1 | none | none | none | good |
| E32 | 0.1 | 0.0005 | 200:1 | none | good | good | good |

Good initial adhesion can be achieved for all catalyst ratios by curing at 120 seconds. By adjusting the catalyst ratio and/or the mixed catalyst level in the coating composition, good initial adhesion can also be achieved for shorter cure times.

Note that not all of the activities described above in the general description or the examples are required, that a portion of a specific activity may not be required, and one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that one or more modifications or one or more other changes can be made without departing from the scope of the invention as set forth in the claims below. Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof has been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all of the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any sub-combination. Further, references to values stated in ranges include each and every value within that range.

What is claimed is:

1. A liquid fluoropolymer coating composition comprising:
a fluoropolymer selected from homopolymers and copolymers of vinyl fluoride and homopolymers and copolymers of vinylidene fluoride;
a mixed catalyst comprising:
a main catalyst comprising an organotin compound; and
a co-catalyst;
solvent;
a compatible cross-linkable adhesive polymer; and
a cross-linking agent.

2. The liquid fluoropolymer coating composition of claim 1, wherein the organotin compound is selected from the group consisting of dibutyl tin dilaurate, dibutyl tin dichloride, stannous octanoate, dibutyl tin dilaurylmercaptide, dibutyltin diisooctylmaleate, and mixtures thereof.

3. The liquid fluoropolymer coating composition of claim 1, wherein the co-catalyst is selected from the group consisting of organozinc compounds, organobismuth compounds, and mixtures thereof.

4. The liquid fluoropolymer coating composition of claim 1, wherein the compatible cross-linkable adhesive polymer comprises polycarbonate polyol.

5. The liquid fluoropolymer coating composition of claim 1, wherein the cross-linking agent comprises a blocked isocyanate functional compound.

6. The liquid fluoropolymer coating composition of claim 1 further comprising pigment.

7. The liquid fluoropolymer coating composition of claim 6, wherein the pigment comprises titanium dioxide.

8. The liquid fluoropolymer coating composition of claim 1, wherein the mixed catalyst has a solids weight ratio of main catalyst to co-catalyst in a range of from about 0.005:1 to about 200:1.

9. The liquid fluoropolymer coating composition of claim 8, wherein the solids weight ratio is in a range of from about 0.1:1 to about 2:1.

10. The liquid fluoropolymer coating composition of claim 1, wherein the main catalyst is present in a range of from about 0.005 to about 0.1 parts per hundred parts fluoropolymer resin solids.

11. The liquid fluoropolymer coating composition of claim 10, wherein the main catalyst is present in a range of from about 0.01 to about 0.02 parts per hundred parts fluoropolymer resin solids.

12. The liquid fluoropolymer coating composition of claim 1, wherein the co-catalyst is present in a range of from about 0.05 to about 1 parts per hundred parts fluoropolymer resin solids.

13. The liquid fluoropolymer coating composition of claim 12, wherein the co-catalyst is present in a range of from about 0.1 to about 0.2 parts per hundred parts fluoropolymer resin solids.

14. A fluoropolymer coated film comprising:
a polymeric substrate film; and
a fluoropolymer coating on the polymeric substrate film, the fluoropolymer coating comprising:
a fluoropolymer selected from homopolymers and copolymers of vinyl fluoride and homopolymers and copolymers of vinylidene fluoride;
a compatible cross-linked adhesive polymer; and
a mixed catalyst comprising:
a main catalyst comprising an organotin compound; and
a co-catalyst;
wherein the polymeric substrate film comprises functional groups that interact with the compatible cross-linked adhesive polymer to promote bonding of the fluoropolymer coating to the polymeric substrate film.

15. The fluoropolymer coated film of claim 14, wherein the co-catalyst is selected from the group consisting of organozinc compounds, organobismuth compounds, and mixtures thereof.

16. The fluoropolymer coated film of claim 14, wherein the fluoropolymer coating further comprises pigment.

17. The fluoropolymer coated film of claim 16, wherein the pigment comprises titanium dioxide.

18. The fluoropolymer coated film of claim 14, wherein the compatible cross-linked adhesive polymer is selected from polyester urethanes, polycarbonate urethanes, acrylic polyurethanes, polyether urethanes, ethylene vinyl alcohol copolymer urethanes, polyamide urethanes, polyacrylamide urethanes and combinations thereof.

19. The fluoropolymer coated film of claim 14, wherein the polymeric substrate film comprises polyester, polyamide, polyimide, or any combination thereof.

20. A backsheet for a photovoltaic module comprising the fluoropolymer coated film of claim 14.

21. A process for forming a fluoropolymer coated film comprising:
coating a polymeric substrate film with a liquid fluoropolymer coating, wherein the liquid fluoropolymer coating comprises:
a fluoropolymer selected from homopolymers and copolymers of vinyl fluoride and homopolymers and copolymers of vinylidene fluoride;
a mixed catalyst comprising:
a main catalyst comprising an organotin compound; and
a co-catalyst;
solvent;
a compatible cross-linkable adhesive polymer; and
a cross-linking agent;
cross-linking the compatible cross-linkable adhesive polymer to form a cross-linked polymer network in the fluoropolymer coating;
removing the solvent from the fluoropolymer coating; and
adhering the fluoropolymer coating to the polymeric substrate film.
